(19) United States
(12) Patent Application Publication
(10) Pub. No.: US 2008/0149178 A1
(43) Pub. Date: Jun. 26, 2008

(54) Composite organic materials and applications thereof

(76) Inventors: Marisol Reyes-Reyes, Winston-Salem, NC (US); Kyungkon Kim, Winston-Salem, NC (US); David L. Carroll, Winston-Salem, NC (US)

Correspondence Address: KILPATRICK STOCKTON LLP, 1001 WEST FOURTH STREET, WINSTON-SALEM, NC, 27101, US

(21) Appl. No.: 11/823,352

(22) Filed: Jun. 27, 2007

Related U.S. Application Data
(60) Provisional application No. 60/816,962, filed on Jun. 27, 2006.
(60) Provisional application No. 60/925,264, filed on Apr. 19, 2007.

(51) Int. Cl. H01L 31/036; H01B 1/12; H01L 31/04; B32B 27/00; B05D 5/12

(52) U.S. Cl. 136/263; 427/74; 252/500; 252/511; 428/220

(57) ABSTRACT

The present invention provides composite organic materials and optoelectronic device, including photovoltaic devices, comprising the same. In one embodiment, a composite material comprises a polymeric phase and a nanoparticle phase, the nanoparticle phase comprising at least one exaggerated nanocrystalline grain.

### RELATED APPLICATION DATA

The present application hereby claims priority under 35 U.S.C. § 119(e) to U.S. Provisional Patent Application Ser. No. 60/816,962 filed Jun. 27, 2006 and U.S. Provisional Patent Application Ser. No. 60/925,264 filed Apr. 19, 2007.

### STATEMENT OF GOVERNMENT LICENSE RIGHTS

This invention was made through the support of the Department of Defense (United States Air Force Office of Scientific Research (AFOSR) Grant No. FA9550-04-1-0161). The Federal Government may retain certain license rights in this invention.

### FIELD OF THE INVENTION

The present invention relates to organic thin films and, in particular, to composite organic thin films.

### BACKGROUND OF THE INVENTION

Organic thin films have been heavily investigated in recent years due to their applications in optoelectronic devices such as organic light emitting devices (OLEDs), photovoltaic devices, and organic photodetectors.

Optoelectronic devices based on organic materials, including organic thin films, are becoming increasingly desirable in a wide variety of applications for a number or reasons. Materials used to construct organic optoelectronic devices are relatively inexpensive in comparison to their inorganic counterparts thereby providing cost advantages over optoelectronic devices produced with inorganic materials. Moreover, organic materials provide desirable physical properties, such as flexibility, permitting their use in applications unsuitable for rigid materials.

Photovoltaic devices convert electromagnetic radiation into electricity by producing a photo-generated current when connected across a load and exposed to light. The electrical power generated by photovoltaic cells can be used in many applications including lighting, heating, battery charging, and powering devices requiring electrical energy.

When irradiated under an infinite load, a photovoltaic device produces its maximum possible voltage, the open circuit voltage or V_{oc}. When irradiated with its electrical contacts shorted, a photovoltaic device produces its maximum current, I short circuit or I_{sc}. Under operating conditions, a photovoltaic device is connected to a finite load, and the electrical power output is equal to the product of the current and voltage. The maximum power generated by a photovoltaic device cannot exceed the product of V_{oc} and I_{sc}. When the load value is optimized for maximum power generation, the current and voltage have the values Iₘₐₓ and Vₘₐₓ respectively.

A key characteristic in evaluating a photovoltaic cell's performance is the fill factor,ff The fill factor is the ratio of the photovoltaic cell's actual power to its power if both current and voltage were at their maxima. The fill factor of a photovoltaic cell is provided according to equation (1).

ff=(IₘₐₓVₘₐₓ)/(I_{sc}V_{oc}) (1)

The fill factor of a photovoltaic is always less than 1, as I_{sc} and V_{oc} are never obtained simultaneously under operating conditions. Nevertheless, as the fill factor approaches a value of 1, a device demonstrates less internal resistance and, therefore, delivers a greater percentage of electrical power to the load under optimal conditions.

Photovoltaic devices may additionally be characterized by their efficiency of converting electromagnetic energy into electrical energy. The conversion efficiency, ηₚ, of a photovoltaic device is provided according to equation (2) where P_{inc} is the power of the light incident on the photovoltaic.

ηₚ=ff*(I_{sc}V_{oc})/P_{inc} (2)

Devices utilizing crystalline or amorphous silicon dominate commercial applications, and some have achieved efficiencies of 23% or greater. However, efficient crystalline-based devices, especially ones of large surface area, are difficult and expensive to produce due to the problems in fabricating large crystals free from crystalline defects that promote exciton recombination. Commercially available amorphous silicon photovoltaic cells demonstrate efficiencies ranging from about 4 to 12%.

Constructing organic photovoltaic devices having efficiencies comparable to inorganic devices poses a technical challenge. Some organic photovoltaic devices demonstrate efficiencies on the order of 1% or less. The low efficiencies displayed in organic photovoltaic devices results from a severe length scale mismatch between exciton diffusion length (L_{D}) and organic layer thickness. In order to have efficient absorption of visible electromagnetic radiation, an organic film must have a thickness of about 500 nm. This thickness greatly exceeds exciton diffusion length which is typically about 50 nm, often resulting in exciton recombination.

It would be desirable to provide composite materials, including organic thin films, that permit efficient absorption of electromagnetic radiation while reducing exciton recombination. In view of the advantages of organic optoelectronic devices discussed herein, it would also be desirable to provide photovoltaic devices comprising composite materials operable to demonstrate conversion efficiencies comparable to, and, in some cases, greater than inorganic photovoltaic devices.

### SUMMARY

The present invention provides composite organic materials and optoelectronic devices, including photovoltaic devices, comprising the same.

In one embodiment, the present invention provides a composite material comprising a polymeric phase and a nanoparticle phase, the nanoparticle phase comprising at least one exaggerated nanocrystalline grain. An exaggerated nanocrystalline grain, as used herein, refers to a crystalline nanoparticle formed from a plurality of nanoparticles, such as carbon nanoparticles, during exaggerated or abnormal grain growth. In some embodiments, the nanoparticle phase comprises a plurality of exaggerated nanocrystalline grains. A composite material, in some embodiments, comprises an organic thin film.

In another embodiment, the present invention provides a photovoltaic cell comprising a radiation transmissive first electrode and a photosensitive composite organic layer electrically connected to first electrode, the photosensitive composite organic layer comprising a polymeric phase and a nanoparticle phase, wherein the nanoparticle phase comprises at least one exaggerated nanocrystalline grain. A second electrode is also electrically connected to the photosensitive composite organic layer.

In a further embodiment, the present invention provides a photoactive apparatus comprising at least one pixel comprising at least one photovoltaic cell, the photovoltaic cell comprising a radiation transmissive first electrode, a photosensitive composite organic layer electrically connected to the first electrode the photosensitive composite organic layer comprising a polymeric phase and a nanoparticle phase, wherein the nanoparticle phase comprises at least one exaggerated nanocrystalline grain, and a second electrode electrically connected to the photosensitive composite organic layer.

In another aspect, the present invention provides methods of producing composite materials and devices comprising the same. In one embodiment, a method for producing a composite material comprises dispersing a nanoparticle phase in a polymeric phase and forming at least one exaggerated nanocrystalline grain in the polymeric phase. In some embodiments, forming at least one exaggerated nanocrystalline grain comprises annealing the composite material in a thermal gradient.

In another embodiment, a method of producing a photovoltaic cell comprises providing a radiation transmissive first electrode, disposing a photosensitive composite organic layer in electrical communication with the first electrode, the composite organic layer comprising a polymeric phase and a nanoparticle phase, disposing a second electrode in electrical communication with the photosensitive composite organic layer, and forming at least one exaggerated nanocrystalline grain in the polymeric phase of the photosensitive composite organic layer. In some embodiments, a photosensitive composite organic layer comprises a thin film.

In a further aspect, the present invention additionally provides methods of converting electromagnetic energy into electrical energy. In one embodiment, a method of converting electromagnetic energy into electrical energy comprises exposing a photosensitive composite organic layer to electromagnetic radiation, the photosensitive composite organic layer comprising a polymeric phase and a nanoparticle phase, generating excitons in the photosensitive composite organic layer, and separating the excitons into electrons and holes at a heterojunction in the composite organic layer. In embodiments of converting electromagnetic energy into electrical energy, the nanoparticle phase of the photosensitive composite organic layer comprises at least one exaggerated nanocrystalline grain. In some embodiments, electromagnetic energy comprises visible electromagnetic energy, infrared electromagnetic energy, ultraviolet electromagnetic energy, or combinations thereof.

These and other embodiments of the present invention are described in greater detail in the detailed description of the invention which follows.

### BRIEF DESCRIPTION OF THE FIGURES

FIG. 1 illustrates a composite organic layer according to an embodiment of the present invention.

FIG. 2 illustrates a photovoltaic cell according to an embodiment of the present invention.

FIG. 3 illustrates a process for establishing a thermal gradient for annealing a photosensitive composite organic layer of a photovoltaic cell according to an embodiment of the present invention.

FIG. 4 illustrates current-voltage plots for photovoltaic cells comprising annealed and un-annealed composite organic layers according to an embodiment of the present invention.

### DETAILED DESCRIPTION

The present invention provides composite organic materials and optoelectronic devices, including photovoltaic devices, comprising the same.

In one embodiment, the present invention provides a composite material comprising a polymeric phase and a nanoparticle phase, the nanoparticle phase comprising at least one exaggerated nanocrystalline grain. In some embodiments, the nanoparticle phase comprises a plurality of exaggerated nanocrystalline grains. A composite material, in some embodiments, comprises an organic thin film.

Turning now to components that can be included in various embodiments of composite materials of the present invention, composite materials comprise a polymeric phase. In some embodiments, the polymeric phase of a composite material comprises one or more conjugated polymers. Conjugated polymers suitable for use in the polymeric phase, according to some embodiments, comprise poly(3-hexylthiophene) (P3HT), poly(3-octylthiophene) (P3OT), and polythiophene (PTh).

In other embodiments, the polymeric phase of a composite material comprises one or more semiconducting polymers. Semiconducting polymers suitable for use in the polymeric phase, in some embodiments, comprise phenylene vinylenes, such as poly(phenylene vinylene), poly(p-phenylene vinylene) (PPV), and derivatives thereof. In another embodiment, suitable semiconducting polymers comprise polyfluorenes, naphthalenes, and derivatives thereof. In a further embodiment, semiconducting polymers for use in the polymeric phase comprise poly(2-vinylpyridine) (P2VP), polyamides, poly(N-vinylcarbazole) (PVCZ), polypyrrole (PPy), and polyaniline (PAn).

In addition to the polymeric phase, composite materials of the present invention comprise a nanoparticle phase dispersed in the polymeric phase. In embodiments of the present invention, the nanoparticle phase comprises at least one exaggerated nanocrystalline grain. In some embodiments, the nanoparticle phase comprises a plurality of exaggerated nanocrystalline grains.

Exaggerated nanocrystalline grains, according to embodiments of the present invention, comprise a plurality of nanoparticles. In one embodiment, nanoparticles of an exaggerated nanocrystalline grain comprise carbon nanoparticles. Carbon nanoparticles, according to some embodiments, comprise multi-walled carbon nanotubes (MWNT), single-walled carbon nanotubes (SWNT), cut nanotubes, nanotubes comprising frequency converters, doped nanotubes, and/or mixtures thereof. In some embodiments, doped nanotubes comprise single and multi-walled carbon nanotubes doped with nitrogen and/or boron. In other embodiments, carbon nanoparticles of exaggerated nanocrystalline grains comprise fullerenes, including fullerene conjugates such as 1-(3-methoxycarbonyl)propyl-1-phenyl-(6,6)C₆₁ (PCBM), higher order fullerenes (C₇₀ and higher), and endometallogfullerenes (fullerenes having at least one metal atom disposed therein). In some embodiments, an exaggerated nanocrystalline grain comprises a plurality of different types of carbon nanoparticles. In one embodiment, for example, an exaggerated nanocrystalline grain can comprise doped and undoped carbon nanotubes.

In some embodiments, nanoparticles of exaggerated nanocrystalline grains comprise metal nanoparticles such as gold nanoparticles, silver nanoparticles, copper nanoparticles, nickel nanoparticles, and other transition metal nanoparticles. In a further embodiment, nanoparticles of exaggerated nanocrystalline grains comprise semiconductor nanoparticles such as III/V and IIVI semiconductor nanoparticles, including cadmium selenide (CdSe) nanoparticles, gallium nitride (GaN) nanoparticles, gallium arsenide (GaAs) nanoparticles, and indium phosphide (InP) nanoparticles.

In one embodiment, an exaggerated nanocrystalline grain can have a length ranging from about 50 nm to about 500 nm. In other embodiments, an exaggerated nanocrystalline grain can have a length ranging from about 100 nm to about 400 nm. In another embodiment, an exaggerated nanocrystalline grain can have a length ranging from about 200 nm to about 300 nm. In a further embodiment, an exaggerated nanocrystalline grain can have a length greater than about 500 nm.

An exaggerated nanocrystalline grain, according to some embodiments, can have a diameter ranging from about 1 nm to about 100 nm. In other embodiments, an exaggerated nanocrystalline grain can have a diameter ranging from about 10 nm to about 90 nm. In another embodiment, an exaggerated nanocrystalline grain can have a diameter ranging from about 20 nm to about 80 nm or from about 30 nm to about 70 nm. In a further embodiment, an exaggerated nanocrystalline grain can have a diameter greater than about 50 nm.

Exaggerated nanocrystalline grains, in some embodiments, demonstrate high aspect ratios.

In addition to exaggerated nanocrystalline grains, a nanoparticle phase of a composite material, in some embodiments of the present invention, also comprises a plurality of individual nanoparticles not associated with an exaggerated nanocrystalline grain, including carbon nanotubes, fullerenes, and conjugates and derivatives thereof.

A composite material, in some embodiments of the present invention, has a ratio of polymeric phase to nanoparticle phase ranging from about 1:2 to about 1:0.6. In other embodiments, a composite material has a ratio of polymeric phase to nanoparticle phase ranging from about 1:1 to about 1:0.3. In one embodiment, for example, the ratio of poly(3-hexylthiophene) to PCBM ranges from about 1:1 to about 1:0.4.

Composite materials comprising a polymeric phase and a nanoparticle phase, the nanoparticle phase comprising at least one exaggerated nanocrystalline grain, in some embodiments of the present invention, are photosensitive being operable to absorb electromagnetic radiation to produce excitons in the composite material. In one embodiment, composite materials of the present invention are operable to absorb visible electromagnetic radiation, infrared electromagnetic radiation, ultraviolet electromagnetic radiation, or combinations thereof.

Composite materials, according to some embodiments of the present invention, further comprise one or more upconverters. As understood by one of skill in the art, an upconverter is a material operable to emit electromagnetic radiation having energy greater than that of the electromagnetic radiation absorbed by the material to create the excited state. Upconverters suitable for use in the present invention, in some embodiments, can absorb infrared radiation and emit visible radiation at wavelengths operable to be absorbed by composite materials of the present invention. Upconverter materials, in some embodiments, can be dispersed throughout the polymeric phase of the composite material.

Upconverters, in some embodiments, include materials comprising at least one Lanthanide series element. In some embodiments, upconverter materials comprise nanoparticles comprising at least one Lanthanide series element. Lanthanide series elements suitable for use in upconverter materials according to some embodiments of the present invention comprise erbium, ytterbium, dysprosium, holmium, or mixtures thereof. In some embodiments, upconverter materials comprise metal oxides and metal sulfides doped with ions of erbium, ytterbium, dysprosium, holmium, or mixtures thereof.

In other embodiments, upconverter materials comprise organic chemical species. Organic upconverter materials can comprise H₂C₆N and 4-dialkylamino-1,8-naphthalimides as well as 1,8-naphthalimide derivatives and compounds, such as multibranched naphthalimide derivatives TPA-NA1, TPA-NA2, and TPA-NA3. Organic upconverter materials can also comprise 4-(dimethylamino)cinnamonitrile (cis and trans), trans-4-[4-(dimethylamino)styryl]-1-methylpyridinium iodide, 4-[4-(dimethylamino)styryl]pyridine, 4-(diethylamino)benzaldehyde diphenylhydrazone, trans-4-[4-(dimethylamino)styryl]-1methylpyridinium p-toluenesulfonate, 2-[ethyl[4-[2-(4-nitrophenyl)ethenyl]phenyl] amino] ethanol, 4-dimethylamino-4′-nitrostilbene, Disperse Orange 25, Disperse Orange 3, and Disperse Red 1.

In a further embodiment, upconverter materials can comprise quantum dots. Quantum dots, according to some embodiments, comprise III/V and II/VI semiconductor materials, such as cadmium selenide (CdSe), cadmium telluride (CdTe), and zinc selenide (ZnSe). Upconverter materials, in some embodiments, also comprise core-shell architectures of quantum dots. The inclusion of III/V and II/VI semiconductor materials as upconverters in a composite material is separate from their use in an exaggerated nanocrystalline grain as contemplated herein.

In some embodiments, a composite material further comprises small molecules. In one embodiment, small molecules suitable for use in a composite material comprise coumarin 6, coumarin 30, coumarin 102, coumarin 110, coumarin 153, and coumarin 540. In another embodiment, small molecules suitable for use in a composite material of the present invention comprise 9,10-dihydrobenzo[a]pyrene-7(8H)-one, 7-methylbenzo[a]pyrene, pyrene, benzo[e]pyrene, 3,4-dihydroxy-3-cyclobutene-1,2-dione, and 1,3-bis[4-(dimethylamino)phenyl-2,4-dihydroxycyclobutenediylium dihydroxide.

Composite materials, according to some embodiments of the present invention, have thickness ranging from about 30 nm to about 1 μm. In other embodiments, composite materials have a thickness ranging from about 80 nm to about 800 nm. In a further embodiment, a composite material has a thickness ranging from about 100 nm to about 300 nm.

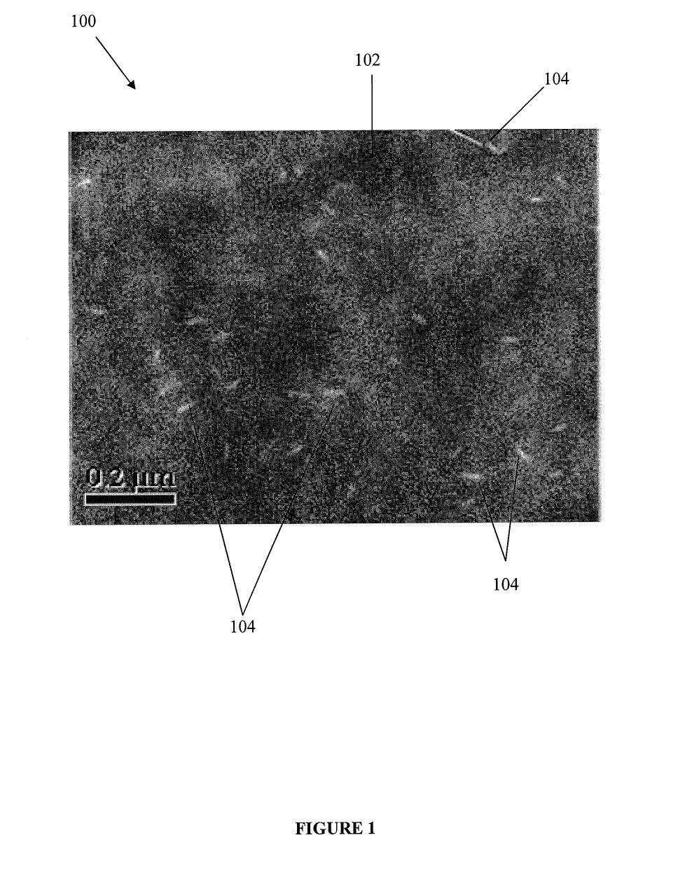

FIG. 1 illustrates a composite material according to one embodiment of the present invention. As displayed in FIG. 1, the composite material (100) comprises a polymeric phase (102) and a nanoparticle phase comprising a plurality of exaggerated nanocrystalline grains (104) dispersed throughout the polymeric phase (102).

In another aspect, the present invention provides a photovoltaic cell comprising a radiation transmissive first electrode and a photosensitive composite organic layer electrically connected to the first electrode, the photosensitive composite organic layer comprising a polymeric phase and a nanoparticle phase, wherein the nanoparticle phase comprises at least one exaggerated nanocrystalline grain. A second electrode is also electrically connected to the photosensitive composite organic layer.

Turning now to components that can be included in photovoltaic cells of the present invention, photovoltaic voltaic cells of the present invention comprise a radiation transmissive first electrode. Radiation transmissive, as used herein, refers to the ability to at least partially pass radiation in the visible, near infrared, and/or near ultraviolet region of the electromagnetic spectrum. In some embodiments, radiation transmissive materials can pass visible electromagnetic radiation with minimal absorbance or other interference.

Moreover, electrodes, as used herein, refer to layers that provide a medium for delivering photo-generated current to an external circuit or providing bias voltage to the optoelectronic device. An electrode provides the interface between the photosensitive composite organic layer of a photovoltaic cell and a wire, lead, trace, or other means for transporting the charge carriers to or from the external circuit.

A radiation transmissive first electrode, according to some embodiments of the present invention, comprises a radiation transmissive conducting oxide. Radiation transmissive conducting oxides, in some embodiments, can comprise indium tin oxide (ITO), gallium indium tin oxide (GITO), and zinc indium tin oxide (ZITO). In another embodiment, the radiation transmissive first electrode can comprise a radiation transmissive polymeric material such as polyaniline (PANI) and its chemical relatives.

In some embodiments, 3,4-polyethylenedioxythiophene (PEDOT) can be a suitable radiation transmissive polymeric material for the first electrode. In other embodiments, a radiation transmissive first electrode can comprise a metal or carbon nanotube layer having a thickness operable to at least partially pass visible electromagnetic radiation.

In some embodiments, a radiation transmissive first electrode has a thickness ranging from about 10 nm to about 1 μm. In other embodiments, a radiation transmissive first electrode has a thickness ranging from about 100 nm to about 900 nm. In another embodiment, a radiation transmissive first electrode has a thickness ranging from about 200 nm to about 800 nm. In a further embodiment, a radiation transmissive first electrode has a thickness greater than 1 μm.

In addition to a radiation transmissive first electrode, photovoltaic cells of the present invention also comprise a photosensitive composite organic layer comprising a polymeric phase and a nanoparticle phase, as provided herein, electrically connected to the radiation transmissive first electrode. In embodiments of the present invention, excitons are generated in the photosensitive composite organic layer upon the absorption of electromagnetic radiation by the polymeric phase. Photosensitive composite organic layers, according to embodiments of the present invention, are operable to absorb visible electromagnetic radiation, infrared electromagnetic radiation, ultraviolet electromagnetic radiation, or combinations thereof. Exciton dissociation can be precipitated at bulk heterojunctions in the composite organic layer. Bulk heterojunctions are formed between adjacent donor and acceptor materials in the photosensitive composite organic layer.

In the context of organic materials, the terms donor and acceptor refer to the relative positions of the highest occupied molecular orbital (HOMO) and lowest unoccupied molecular orbital (LUMO) energy levels of two contacting but different organic materials. This is in contrast to the use of these terms in the inorganic context, where donor and acceptor may refer to types of dopants that may be used to create inorganic n- and p-type layers, respectively. In the organic context, if the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

In embodiments of the present invention, the polymeric phase of the composite organic layer serves as a donor material and the nanoparticle phase serves as the acceptor material thereby forming heterojunctions operable for the separation of excitons into holes and electrons. Heterojunctions, according to embodiments of the present invention, are formed between polymers of the polymeric phase and nanoparticles, including exaggerated nanocrystalline grains, of the nanoparticle phase dispersed throughout the polymeric phase. In some embodiments, the high aspect ratio and crystalline structure of exaggerated nanocrystalline grains provide separated excitons (electrons) a faster pathway to an electrode thereby decreasing the likelihood of recombination and enhancing photovoltaic cell efficiency.

Photovoltaic cells of the present invention comprise a second electrode electrically connected to the photosensitive composite organic layer. In some embodiments, the second electrode comprises a metal. As used herein, metal refers to both materials composed of an elementally pure metal, e.g., gold, and also metal alloys comprising materials composed of two or more elementally pure materials. In some embodiments, the second electrode comprises gold, silver, aluminum, or copper. The second electrode, according to some embodiments, can have a thickness ranging from about 10 nm to about 10 μm. In other embodiments, the second electrode can have a thickness ranging from about 100 nm to about 1 μm or from about 200 nm to about 800 nm. In a further embodiment, the second electrode can have a thickness ranging from about 50 nm to about 500 nm.

A layer comprising lithium fluoride (LiF), according to some embodiments, is disposed between the photosensitive composite organic layer and second electrode. The LiF layer can have a thickness ranging from about 1 angstroms to about 10 angstroms.

In some embodiments, the LiF layer can be at least partially oxidized resulting in a layer comprising lithium oxide (Li₂O) and LiF. In other embodiments, the LiF layer can be completely oxidized resulting in a lithium oxide layer deficient or substantially deficient of LiF. In some embodiments, a LiF layer is oxidized by exposing the LiF layer to oxygen, water vapor, or combinations thereof. In one embodiment, for example, a LiF layer is oxidized to a lithium oxide layer by exposure to an atmosphere comprising water vapor and/or oxygen at a partial pressures of less than about 10⁻⁶ Torr. In another embodiment, a LiF layer is oxidized to a lithium oxide layer by exposure to an atmosphere comprising water vapor and/or oxygen at a partial pressures less than about 10⁻⁷ Torr or less than about 10⁻⁸ Torr. A partially oxidized or completely oxidized LiF layer, in some embodiments, has a thickness ranging from about 1 angstrom to about 10 angstroms.

In some embodiments, a LiF layer is exposed to an atmosphere comprising water vapor and/or oxygen for a time period ranging from about 1 hour to about 15 hours. In one embodiment, a LiF layer is exposed to an atmosphere comprising water vapor and/or oxygen for a time period greater than about 15 hours. In a further embodiment, a LiF layer is exposed to an atmosphere comprising water vapor and/or oxygen for a time period less than about one hour. The time period of exposure of the LiF layer to an atmosphere comprising water vapor and/or oxygen, according to some embodiments of the present invention, is dependent upon the partial pressures of the water vapor and/or oxygen in the atmosphere. The higher the partial pressure of the water vapor or oxygen, the shorter the exposure time.

Photovoltaic cells of the present invention, in some embodiments, further comprise additional layers such as one or more exciton blocking layers. In embodiments of the present invention, an exciton blocking layer (EBL) can act to confine photogenerated excitons to the region near the dissociating interface and prevent parasitic exciton quenching at a photosensitive organic/electrode interface. In addition to limiting the path over which excitons may diffuse, an EBL can additionally act as a diffusion barrier to substances introduced during deposition of the electrodes. In some embodiments, an EBL can have a sufficient thickness to fill pin holes or shorting defects which could otherwise render an organic photovoltaic device inoperable.

An EBL, according to some embodiments of the present invention, can comprise a polymeric material. In embodiment, an EBL can comprise polyethylenedioxythiophene:polystyrenesulfonate (PEDOT:PSS). In another embodiment, an EBL can comprise a composite material. In one embodiment, an EBL comprises carbon nanoparticles dispersed in 3,4-polyethylenedioxythiophene:polystyrenesulfonate (PEDOT:PSS). In another embodiment, an EBL comprises carbon nanoparticles dispersed in poly(vinylidene chloride) and copolymers thereof. Carbon nanoparticles dispersed in the polymeric phases including PEDOT:PSS and poly(vinylidene chloride) can comprise single-walled nanotubes, multi-walled nanotubes, fullerenes, or mixtures thereof. In further embodiments, EBLs can comprise any polymer having a work function energy operable to permit the transport of holes while impeding the passage of electrons. In some embodiments, an EBL may be disposed between the radiation transmissive first electrode and a photosensitive composite organic layer of a photovoltaic cell.

In some embodiments, a photovoltaic cell can be disposed on a rigid or flexible radiation transmissive substrate. A rigid substrate, according to some embodiments, can comprise glass, a thermoplastic, thermoset, or metal.

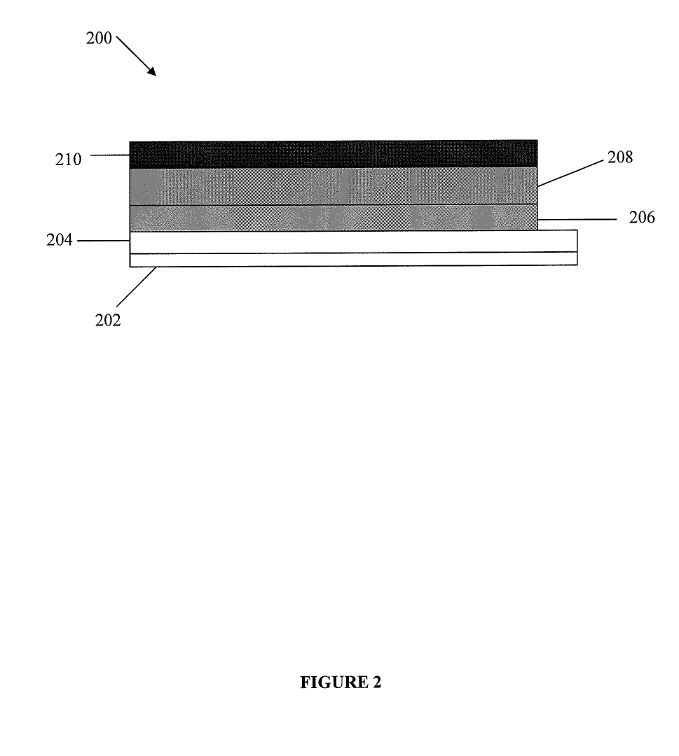

FIG. 2 illustrates a cross-sectional view of photovoltaic cell according to an embodiment of the present invention. The photovoltaic cell (200) shown in FIG. 2 comprises a radiation transmissive substrate (202) and a radiation transmissive first electrode (204) comprising a conducting oxide, such as indium tin oxide, gallium indium tin oxide, or zinc indium tin oxide. An exciton blocking layer (206) is disposed over the radiation transmissive first electrode (204). As provided herein, in some embodiments, the exciton blocking layer (206) can comprise PEDOT. The exciton blocking layer (206) is covered by a photosensitive composite organic layer (208) comprising a polymeric phase and a nanoparticle phase. The nanoparticle phase of the composite organic layer (208) comprises at least one exaggerated nanocrystalline grain. A second electrode (210) resides above the composite organic layer (208). In some embodiments, the second electrode comprises a metal such as aluminum, gold, solver, nickel or copper.

Photovoltaic cells, according to some embodiments of the present invention, can display a fill factor greater than about 0.2. In other embodiments, a photovoltaic cells can demonstrate a fill factor greater than about 0.5. In a further embodiment, a photovoltaic cells can display a fill factor greater than about 0.7.

In some embodiments, a photovoltaic cell of the present invention can display a conversion efficiency, ηₚ, greater than about 4%. Photovoltaic cells of the present invention, in other embodiments, can display a conversion efficiency greater than about 5%. In a further embodiment, a photovoltaic cell of the present invention can demonstrate a conversion efficiency greater than about 6%.

In another aspect, the present invention provides a photoactive apparatus comprising at least one pixel comprising at least one photovoltaic cell, the photovoltaic cell comprising a radiation transmissive first electrode, a photosensitive composite organic layer electrically connected to the first electrode, the photosensitive organic layer comprising a polymeric phase and a nanoparticle phase, wherein the nanoparticle phase comprises at least one exaggerated nanocrystalline grain. A second electrode is electrically connected to the composite organic layer.

In some embodiments, a pixel comprises a plurality of photovoltaic cells. In other embodiments, a photoactive apparatus comprises a plurality of pixels. In a further embodiment, a photoactive device comprises an array of pixels, each pixel comprising a plurality of photovoltaic cells. In some embodiments, a photoactive apparatus comprises a solar array.

Photovoltaic cells for use in pixel applications, in some embodiments of the present invention, are constructed independently from one another. In such embodiments, component materials for one photovoltaic cell are selected without reference to component materials selected for another photovoltaic cell. In one embodiment, for example, photovoltaic cells can comprise different conjugated polymers having non-overlapping spectral absorbances. As a result, in some embodiments, pixels and pixel arrays are not required to comprise photovoltaic cells of identical construction. Photovoltaic cell construction can be varied in any manner consistent with the materials and methods described herein to produce pixels and pixel arrays suitable for a wide range of applications.

In another aspect, the present invention also provides methods for producing a composite material comprising a polymeric phase and a nanoparticle phase. In one embodiment, a method for producing a composite material comprises disposing a nanoparticle phase in a polymeric phase and forming at least one exaggerated nanocrystalline grain in the polymeric phase. Exaggerated nanocrystalline grains, according to embodiments of the present invention, are formed from a plurality of nanoparticles disposed in the polymeric phase during abnormal or exaggerated grain growth. In one embodiment, for example, an exaggerated nanocrystalline grain is formed from a plurality of carbon nanoparticles, such as fullerenes or carbon nanotubes, disposed in the polymeric phase.

In some embodiments, forming at least one exaggerated nanocrystalline grain comprises annealing the composite material. Annealing, according to some embodiments of the present invention, comprises disposing the composite material in a thermal gradient. In some embodiments, a thermal gradient can be established by heating one side of the composite material while maintaining the opposing side of the composite material at a constant temperature or cooling the opposing side.

In one embodiment, for example, one side of a composite material is exposed to a temperature within about 5% to about 30% of the glass transition temperature (T_{g}) of the polymeric phase while the opposing side is held at or cooled to room temperature. In another embodiment, one side of a composite material is exposed to a temperature within about 10% to about 20% of the glass transition temperature of the polymeric phase while the opposing side is held at or cooled to room temperature.

In other embodiments, one side of a composite organic material can be exposed to a temperature within about 5% to about 30% of the glass transition temperature of the polymeric phase while the opposing side is held at or cooled to a temperature ranging from about room temperature to about liquid nitrogen temperatures. In a further embodiment, one side of a composite material is exposed to a temperature within about 10% to about 20% of the glass transition temperature of the polymeric phase while the opposing side is held at or cooled to a temperature ranging from about room temperature to about liquid nitrogen temperatures. The temperature difference between the heated side of the composite material and the opposing unheated side can be varied depending factors such as thickness of the composite material, loading of the nanoparticle phase in the polymeric phase, and heating times.

In some embodiments, a composite material is annealed for a time period ranging from about 30 seconds to about 15 minutes. In another embodiment, a composite material is annealed for a time period ranging from about 1 minute to about 10 minutes or from about 2 minutes to about 7 minutes. In a further embodiment, a composite material is annealed for a time period less than or equal to about 5 minutes. In one embodiment, a composite material is annealed for a time period ranging from about 2 minutes to about 3 minutes. In some embodiments, a composite material is annealed for a time period greater than about 15 minutes.

While not wishing to be bound to any theory, it is believed that two processes occur when a composite material comprising a polymeric phase and a nanoparticle phase is annealed in a thermal gradient approaching the glass transition temperature of the polymeric phase. First, the polymeric phase undergoes at least some crystallization thereby increasing hole mobilities within the polymeric phase. Second, exaggerated nanocrystalline grains comprising a plurality of nanoparticles form in the polymeric phase as a result of exaggerated or abnormal grain growth processes. The resulting exaggerated nanocrystalline grains, in some embodiments, can be at least partially aligned in the polymeric phase, thereby improving the electron mobility to match the enhanced hole mobility.

In some embodiments, one or more exaggerated nanocrystalline grains can be substantially vertically aligned or oriented in the polymeric phase of a photosensitive composite organic layer.

In a further aspect, the present invention provides methods of producing photovoltaic cells. In one embodiment, a method for producing a photovoltaic cell comprises providing a radiation transmissive first electrode, disposing a photosensitive composite organic layer in electrical communication with the first electrode, the photosensitive composite organic layer comprising a polymeric phase and a nanoparticle phase, disposing a second electrode in electrical communication with the photosensitive composite organic layer, and forming at least one exaggerated nanocrystalline grain in the polymeric phase of the photosensitive composite organic layer.

In some embodiments, disposing a photosensitive composite organic layer in electrical communication with the first electrode comprises depositing the composite organic layer on the first electrode by dip coating, spin coating, vapor phase deposition, or vacuum thermal annealing. Disposing a second electrode in electrical communication with the photosensitive composite organic layer, according to some embodiments, comprises depositing the second electrode on the composite organic layer through vapor phase deposition, spin coating, dip coating, or vacuum thermal annealing.

Forming at least one exaggerated nanocrystalline grain in the polymeric phase, according to embodiments of the present invention, comprises annealing the photosensitive composite organic layer in a thermal gradient as provided hereinabove.

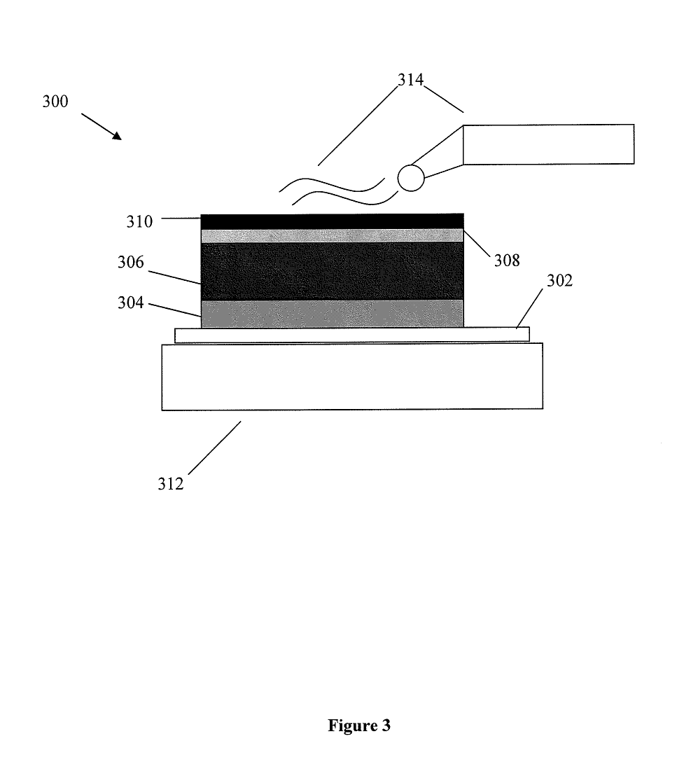

FIG. 3 illustrates a process for establishing a thermal gradient for annealing a photosensitive composite organic layer of a photovoltaic cell according to an embodiment of the present invention. As illustrated in FIG. 3, the photovoltaic cell (300) comprises a radiation transmissive first electrode (302), an exciton blocking layer (304) covering the radiation transmissive first electrode (302), and a photosensitive composite organic layer (306) above the exciton blocking layer. A layer of LiF (308) covers the composite organic layer (306) followed by a second electrode (310).

The photovoltaic cell (300) is positioned on a heating plate (312). The heating plate (312), in some embodiments, is set to a temperature within about 10% to about 20% of the glass transition temperature of the polymeric phase of the composite organic layer (306). A source of flowing inert gas (314), such as nitrogen or argon, is positioned to contact the side of the photovoltaic cell (300) opposing the heating plate (312). In the embodiment shown in FIG. 3, the side opposing the heating plate (312) comprises the second electrode (310). Inert gas (314) flows over the second electrode (310) to cool or maintain the second electrode (310) at a constant temperature. In some embodiments, the side opposing the heating plate can be maintained at a temperature ranging from about room temperature to about liquid nitrogen temperatures. The temperature difference between the opposing sides of the photovoltaic cell (300) establishes the thermal gradient for the annealing process. In some embodiments, the photovoltaic cell (300) is placed in a glove box (not shown) under an inert atmosphere during the annealing process.

In a further aspect, the present invention provides methods of converting electromagnetic energy into electrical energy. In one embodiment, a method for converting electromagnetic energy into electrical energy comprises exposing a photosensitive composite organic layer to electromagnetic radiation, the composite organic layer comprising a polymeric phase and a nanoparticle phase wherein the nanoparticle phase comprises at least one exaggerated nanocrystalline grain, generating excitons in the photosensitive composite organic layer, and separating the excitons into electrons and holes at a heterojunction in the composite organic layer.

In some embodiments, a heterojunction comprises a plurality of bulk heterojunctions. As discussed herein, a bulk heterojunction is formed at the interface of a donor material and an acceptor material. In some embodiments, a donor material comprises the polymeric phase and the acceptor material comprises the nanoparticle phase of the photosensitive composite organic layer. In one embodiment, a bulk heterojunction is formed at the interface of the polymeric phase and at least one exaggerated nanocrystalline grain. In other embodiments, a bulk heterojunction is formed at the interface the polymeric phase and a nanoparticle of the nanoparticle phase, such as a carbon nanotube or a fullerene, not associated with an exaggerated crystalline grain.

A method for converting electromagnetic energy into electrical energy, according to embodiments of the present invention, can further comprise removing the electrons into an external circuit.

### EXAMPLE 1

### Photovoltaic Cell

A non-limiting example of a photovoltaic cell of the present invention was prepared according to the following procedure.

A photovoltaic cell of the present invention was prepared by spin casting poly(3,4-ethylenedioxythiophene):poly(styrenesulfonate) (PEDOT:PSS) (Baytron P) onto a cleaned indium tin oxide (ITO) substrate (Delta Technologies Rₛ=10 Ohm square⁻¹). The PEDOT:PSS layer was about 80 nm thick. A blend of regioregular P3HT (Aldrich: regioregular with an average molecular weight, M_{w}=87 kg mol⁻¹, without further purification) and PCBM (American Dye Source) was subsequently spin coated onto the PEDOT:PSS layer. The ratio of P3HT to PCBM was about 1:0.66. A LiF (0.3-0.4 nm) and aluminum (80 nm) cathode was evaporated onto the polymer stack. The photovoltaic cell was removed from the evaporator and encapsulated using glass capsules with a silicon seal. Once encapsulated, the photovoltaic cell was annealed on a hot plate at about 155° C. for about 3 minutes. Dried nitrogen gas was blown over the side of the photovoltaic cell opposite the heating plate to maintain the side at room temperature during annealing.

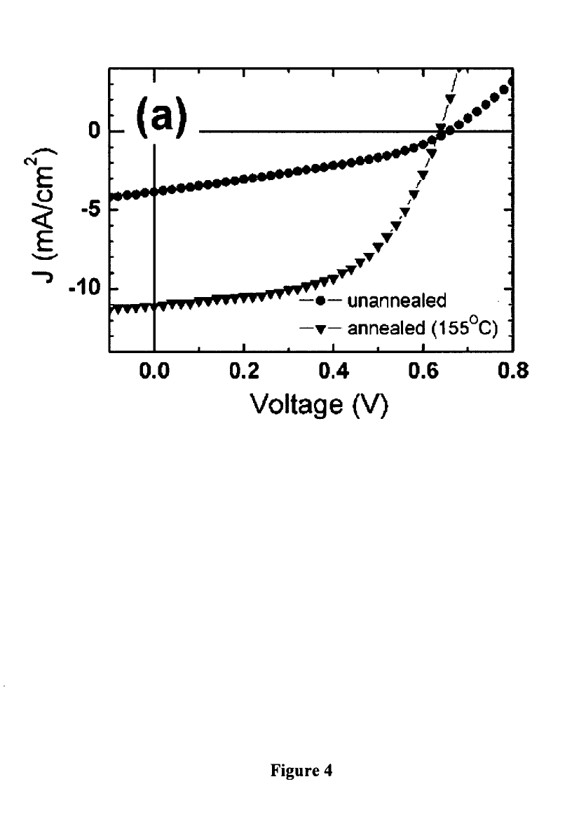

After fabrication, the photovoltaic cell was tested to determine performance characteristics in terms of short circuit current density and open circuit voltage. All photovoltaic cell measurements were performed at room temperature. FIG. 4 illustrates current-voltage (I-V) plots for annealed and unannealed photovoltaic cells. I-V curves of the devices were measured using a Keithley 236 Source Measure Unit. The solar simulator used was an AM1.5G from Oriel. The illumination intensity was 80 mW cm⁻². As displayed in the I-V curves, the short circuit current density of a photovoltaic cell increases subsequent to annealing the photovoltaic cell.

Various embodiments of the invention have been described in fulfillment of the various objects of the invention. It should be recognized that these embodiments are merely illustrative of the principles of the present invention. Numerous modifications and adaptations thereof will be readily apparent to those skilled in the art without departing from the spirit and scope of the invention.

1. A composition comprising:
a composite material comprising a polymeric phase and a nanoparticle phase, the nanoparticle phase comprising at least one exaggerated nanocrystalline grain.

2. The composition of claim 1, wherein the nanoparticle phase comprises a plurality of exaggerated nanocrystalline grains.

3. The composition of claim 1, wherein the polymeric phase comprises a conjugated polymer.

4. The composition of claim 3, wherein the conjugated polymer comprises poly(3-hexylthiophene), poly(octylthiophene), polythiophene, or combinations thereof.

5. The composition of claim 1, wherein the polymeric phase comprises a semiconducting polymer.

6. The composition of claim 5, wherein the semiconducting polymer comprises poly(phenylene vinylene), poly(p-phenylene vinylene), polyfluorenes, poly(2-vinylpyridine) polyamides, poly(N-vinylcarbazole), polypyrrole, polyaniline, or combinations thereof.

7. The composition of claim 1, wherein the at least one exaggerated nanocrystalline grain comprises a plurality of nanoparticles.

8. The composition of claim 7, wherein the nanoparticles comprise carbon nanoparticles.

9. The composition of claim 8, wherein the carbon nanoparticles comprise multi-walled carbon nanotubes, single-walled carbon nanotubes, cut carbon nanotubes, fillerenes, doped carbon nanotubes, or combinations thereof.

10. The composition of claim 9, wherein doped carbon nanotubes comprise boron doped single-walled carbon nanotubes, boron doped multi-walled nanotubes, nitrogen doped single-walled nanotubes, nitrogen doped multi-walled nanotubes, or combinations thereof.

11. The composition of claim 7, wherein the nanoparticles comprise metal nanoparticles.

12. The composition of claim 1, wherein the at least one exaggerated nanocrystalline grain has a length ranging from about 50 nm to about 500 nm.

13. The composition of claim 1, wherein the at least one exaggerated nanocrystalline grain has a diameter ranging from about 1 nm to about 500 nm.

14. The composition of claim 1, wherein the composite material has a ratio of polymeric phase to nanoparticle phase ranging from about 1:2 to about 1:0.6.

15. The composition of claim 1, wherein the composite material further comprises at least one upconverter.

16. The composition of claim 1, wherein the composite material has a thickness ranging from about 30 nm to about 1 μm.

17. A photovoltaic cell comprising:
a radiation transmissive first electrode; and
a photosensitive composite organic layer electrically connected to the first electrode, the photosensitive composite organic layer comprising a polymeric phase and a nanoparticle phase, wherein the nanoparticle phase comprises at least one exaggerated nanocrystalline grain.

18. The photovoltaic cell of claim 17, wherein radiation transmissive first electrode comprises a radiation transmissive conducting oxide.

19. The photovoltaic cell of claim 17, wherein radiation transmissive first electrode comprises a radiation transmissive polymeric material.

20. The photovoltaic cell of claim 17, wherein the nanoparticle phase comprises a plurality of exaggerated nanocrystalline grains.

21. The photovoltaic cell of claim 17, wherein the polymeric phase comprises a conjugated polymer.

22. The photovoltaic cell of claim 21, wherein the conjugated polymer comprises poly(3-hexylthiophene), poly(octylthiophene), polythiophene, or combinations thereof.

23. The photovoltaic cell of claim 17, wherein the polymeric phase comprises a semiconducting polymer.

24. The photovoltaic cell of claim 23, wherein the semiconducting polymer comprises poly(phenylene vinylene), poly(p-phenylene vinylene), polyfluorenes, poly(2-vinylpyridine) polyamides, poly(N-vinylcarbazole), polypyrrole, polyaniline, or combinations thereof.

25. The photovoltaic cell of claim 17, wherein the at least one exaggerated nanocrystalline grain comprises a plurality of nanoparticles.

26. The photovoltaic cell of claim 25, wherein the nanoparticles comprise carbon nanoparticles.

27. The photovoltaic cell of claim 26, wherein the carbon nanoparticles comprise multi-walled carbon nanotubes, single-walled carbon nanotubes, cut carbon nanotubes, fullerenes, doped carbon nanotubes, or combinations thereof.

28. The photovoltaic cell of claim 27, wherein doped carbon nanotubes comprise boron doped single-walled carbon nanotubes, boron doped multi-walled nanotubes, nitrogen doped single-walled nanotubes, nitrogen doped multi-walled nanotubes, or combinations thereof.

29. The photovoltaic cell of claim 25, wherein the nanoparticles comprise metal nanoparticles.

30. The photovoltaic cell of claim 17, wherein the photosensitive composite organic layer has a ratio of polymeric phase to nanoparticle phase ranging from about 1:2 to about 1:0.6.

31. The photovoltaic cell of claim 17, wherein the photosensitive composite organic layer further comprises at least one bulk heterojunction between the polymeric phase and the nanoparticle phase.

32. The photovoltaic cell of claim 17, wherein the photosensitive composite layer further comprises a plurality of bulk heterojunctions between the polymeric phase and the nanoparticle phase.

33. The photovoltaic cell of claim 17 further comprising a second electrode electrically connected to the photosensitive composite organic layer.

34. The photovoltaic cell of claim 33 further comprising an at least partially oxidized layer of lithium fluoride disposed between the photosensitive composite organic layer and the second electrode.

35. The photovoltaic cell of claim 33, further comprising a layer of lithium oxide disposed between the photosensitive composite organic layer and the second electrode.

36. The photovoltaic cell of claim 17, wherein the photovoltaic cell has an efficiency greater than about 5%.

37. The photovoltaic cell of claim 17, wherein the photovoltaic cell has an efficiency greater than about 6%.

38. A photoactive apparatus comprising:
at least one pixel comprising at least one photovoltaic cell, the photovoltaic cell comprising a radiation transmissive first electrode and a photosensitive composite organic layer electrically connected to the first electrode, the photosensitive composite organic layer comprising a polymeric phase and a nanoparticle phase, wherein the nanoparticle phase comprises at least one exaggerated nanocrystalline grain.

39. The photoactive apparatus of claim 38, wherein the at least one pixel comprises a plurality of photovoltaic cells.

40. The photoactive apparatus of claim 38 comprising an array of pixels.

41. The photoactive apparatus of claim 40, wherein each pixel of the array comprises a plurality of photovoltaic cells.

42. The photoactive apparatus of claim 38, wherein the apparatus is a solar collector.

43. A method of producing a composite material comprising:
disposing a nanoparticle phase in a polymeric phase; and
forming at least one exaggerated nanocrystalline grain in the polymeric phase.

44. The method of claim 43, wherein disposing a nanoparticle phase in a polymeric phase comprises dispersing a plurality of nanoparticles in the polymeric phase.

45. The method of claim 43, wherein forming at least one exaggerated nanocrystalline grain comprises annealing the composite material.

46. The method of claim 45, wherein annealing comprises disposing the composite material in a thermal gradient.

47. A method of producing a photovoltaic cell comprising:
providing a radiation transmissive first electrode, disposing a photosensitive composite organic layer in electrical communication with the first electrode, the photosensitive composite organic layer comprising a polymeric phase and a nanoparticle phase;
disposing a second electrode in electrical communication with the photosensitive composite organic layer; and
forming at least one exaggerated nanocrystalline grain in the polymeric phase of the photosensitive composite organic layer.

48. A method of converting electromagnetic energy into electrical energy comprising:
exposing a photosensitive composite organic layer to electromagnetic radiation, the photosensitive composite organic layer comprising a polymeric phase and a nanoparticle phase wherein the nanoparticle phase comprises at least one exaggerated nanocrystalline grain;
generating excitons in the photosensitive composite organic layer; and
separating the excitons into electrons and holes at a heterojunction in the composite organic layer.

49. The method of claim 48, wherein the heterojunction comprises a plurality of bulk heterojunctions.

50. The method of claim 48, wherein the electromagnetic radiation comprises visible electromagnetic radiation, infrared electromagnetic radiation, ultraviolet electromagnetic radiation or combinations thereof.

51. The method of claim 48, further comprising removing the electrons into an external circuit.
